(19) United States
(12) Patent Application Publication
(10) Pub. No.: US 2023/0221545 A1
(43) Pub. Date: Jul. 13, 2023

(54) MICROMECHANICAL COMPONENT

(71) Applicant: Robert Bosch GmbH, Stuttgart (DE)

(72) Inventors: Helmut Grutzeck, Kusterdingen (DE); Frank Schatz, Kornwestheim (DE); Janine Riedrich-Moeller, Leonberg-Warmbronn (DE)

(21) Appl. No.: 18/067,402

(22) Filed: Dec. 16, 2022

(30) Foreign Application Priority Data
Jan. 10, 2022 (DE) 10 2022 200 149.4

(51) Int. Cl. G02B 26/08; H02N 2/00; H02N 2/02; H02N 2/06

(52) U.S. Cl. CPC G02B 26/0858; H02N 2/006; H02N 2/028; H02N 2/06; G02B 26/10

(57) ABSTRACT

A micromechanical component comprising a bracket and an adjustable portion arranged in an adjustable manner on the bracket. The micromechanical component includes a first bender actuator and a first support structure for the first bender actuator. The first bender actuator is arranged in or on the first support structure and is configured to bend the first support structure at least in the area of the first bender actuator arranged in or on the first support structure, such that the adjustable portion is displaceable relative to the bracket about a first rotational axis. The first support structure is directly connected to the adjustable portion. The micromechanical component additionally includes a first spring configured to suspend the first support structure for the first bender actuator and the adjustable portion from the bracket.

### CROSS REFERENCE

The present application claims the benefit under 35 U.S.C. § 119 of German Patent Application No. DE 10 2022 200 149.4 filed on Jan. 10, 2022, which is expressly incorporated herein by reference in its entirety.

### FIELD

The present invention relates to a micromechanical component, in particular to a micromirror device. In addition, the present invention relates to a scanning device, in particular a microscanning device, comprising the micromechanical component.

### BACKGROUND INFORMATION

German Patent Application No. DE 10 2016 208 924 A1 describes a micromirror device as a micromechanical component. The micromirror is resonantly driven by four bender actuators, each of which are arranged individually on wings as support structures for the respective bender actuator.

An object of the present invention is to provide a space-saving micromechanical component.

### SUMMARY

According to an example embodiment of the present invention, a micromechanical component is provided. According to an example embodiment of the present invention, the micromechanical component comprises a bracket and an adjustable portion, which is arranged in an adjustable manner on the bracket. Preferably, the adjustable portion is configured as a micromirror. Preferably, the adjustable portion has a thickness in a range of 50 to 700 μm. Additionally, the micromechanical component comprises a first bender actuator and a first support structure for the first bender actuator. Preferably, the first support structure is formed from silicon. The bender actuator is arranged in or on the first support structure, in particular on an outer surface. In this context, the first bender actuator is configured to bend the first support structure at least in the area of the first bender actuator arranged in or on the first support structure, such that the adjustable portion is displaceable relative to the bracket around a first rotational axis. In this context, the first bender actuator is in particular configured to deform and thus bend the first support structure at least in the area of the first bender actuator arranged in or on the first support structure. By this adjustment movement of the first support structure as a result of the deflection, a reaction force or reaction torque for the adjustable portion relative to the bracket around the first rotational axis and thus a rotational movement of the adjustable portion is generated. The first rotational axis is in particular a rotational axis that runs along a longitudinal axis of the adjustable portion. The first support structure is directly connected to the adjustable portion and thus additionally serves as a type of support for the adjustable portion. Additionally, the micromechanical component comprises a first spring that serves to suspend the first support structure for the first bender actuator and the adjustable portion from the bracket. Significantly less installation space is required due to the sole bender actuator and its support structure.

Preferably, according to an example embodiment of the present invention, the micromechanical component additionally comprises a second spring configured to suspend the first support structure for the first bender actuator and the adjustable portion from the bracket. The micromechanical component is thus made more stable. Preferably, a first point of application of the first spring on the first support structure and a second point of application of the second spring on the first support structure are arranged at an offset from the first rotational axis.

Preferably, according to an example embodiment of the present invention, the micromechanical component comprises a second bender actuator and a second support structure for the second bender actuator. A micromechanical component with two support structures and two associated bender actuators results in a more stable system. In particular, the position of the first rotational axis is more stable with respect to process fluctuations. Preferably, the first support structure is formed from silicon. The second bender actuator is arranged in or on the second support structure, in particular an outer surface. In this context, the second bender actuator is configured to bend the second support structure at least in the area of the second bender actuator arranged in or on the second support structure, such that the adjustable portion is displaceable relative to the bracket around the first rotational axis. In this context, the second bender actuator is in particular configured to deform and thus bend the second support structure at least in the area of the first bender actuator arranged in or on the first support structure. By this adjustment movement of the second support structure as a result of the deflection, a reaction force or reaction torque for the adjustable portion relative to the bracket around the first rotational axis and thus a rotational movement of the adjustable portion is generated. In particular, the first and second support structures are deformed in opposite directions by means of the respective bender actuator. Alternatively, the first and second support structures are deformed in the same direction. The second support structure is directly connected to the adjustable portion and thus additionally serves as a type of support for the adjustable portion. The micromechanical component comprises a third spring configured to suspend the second support structure for the second bender actuator and the adjustable portion from the bracket. Preferably, the first and second support structures engage with the adjustable portion at opposite ends of the adjustable portion. Preferably, a third point of application of the first spring on the first support structure and a fourth point of application of the third spring on the second support structure are substantially arranged on the first rotational axis. The support structures and therefore also the adjustable portion are thus more stably suspended. Some modes below the working frequency may be suppressed accordingly.

Preferably, according to an example embodiment of the present invention, the first spring is directly connected to the first support structure. Alternatively or additionally, the second spring is preferably directly connected to the first support structure. Furthermore, alternatively or additionally, the third spring is preferably directly connected to the second support structure.

Preferably, according to an example embodiment of the present invention, the first bender actuator is configured as a piezoelectric actuator. Alternatively or additionally, the second bender actuator is preferably configured as a piezoelectric actuator. A piezoelectric actuator has the advantage that it can cause relatively large forces to adjust the adjustable portion around the first rotational axis with a comparatively small change in the extension. Additionally, a resonant piezoelectric drive can be operated almost without electricity, and is therefore the ideal drive for high-frequency resonant adjustment movements of the respective adjustable portion.

Preferably, according to an example embodiment of the present invention, the first bender actuator is arranged at an opposite end of the first support structure to the adjustable element. Alternatively or additionally, the second bender actuator is arranged at an opposite end of the second support structure to the adjustable element. At these positions, the largest adjustment movements of the support structures and thus also the largest reaction forces or reaction torques for the adjustable portion relative to the bracket around the first rotational axis result.

Preferably, according to an example embodiment of the present invention, the first support structure is wing-shaped, in particular in a semi-circular wing shape. Alternatively or additionally, the second support structure is wing-shaped, in particular in a semi-circular wing shape.

Preferably, according to an example embodiment of the present invention, the micromechanical component additionally comprises a control device, which is configured to control the first and/or second bender actuators by means of electrical signals such that the adjustable portion can be moved into a resonant oscillating movement around the first rotational axis relative to the bracket. In this context, the first rotational axis may also be referred to as a resonant axis. The control device is preferably configured to provide at least one electrical signal to the first and/or second bender actuators such that the adjustable portion can be moved into a resonant oscillating movement around the first rotational axis relative to the bracket. In resonant operation, the first and second support structures move in the z-direction at least in the area of the respectively arranged bender actuators. In this context, the z-direction refers to the direction that is oriented in a direction vertical to the main extension plane of the adjustable portion in a resting state of the adjustable portion. In the embodiment with only a single, first bender actuator, the resonant movement results in a comparatively higher mode of the first support structure.

Preferably, according to an example embodiment of the present invention, the first and/or second support structure is/are configured as a spring element. This means that the first and/or second support structures each have a spring function with the corresponding flexible deformation properties. Preferably, the first and/or second support structure has/have a thickness in a range from 10 to 50 μm. Preferably, the first and/or second and/or third springs have a lower, in particular a significantly lower, spring stiffness than the first support structure and/or second support structure. In this context, the first and/or second and/or third springs are preferably configured as meander-shaped springs. In contrast, the first and/or second support structure is/are preferably configured as leaf springs with torsion fractions.

A further object of the present invention is to provide a scanning device, in particular a microscanning device, with the micromechanical component described above. In this context, the scanning device is preferably configured as a LIDAR scanner. Alternatively, the scanning device is configured as a microscanner for projection onto a screen or onto the eye of a user of data glasses.

### BRIEF DESCRIPTION OF THE DRAWINGS

FIG. 1 schematically shows a first embodiment of a micromirror device as a micromechanical component, according to the present invention.

FIG. 2 schematically shows a second embodiment of a micromirror device as a micromechanical component, according to the present invention.

FIG. 3 schematically shows a scanning device with the micromechanical component, according to an example embodiment of the present invention.

### DETAILED DESCRIPTION OF EXAMPLE EMBODIMENTS

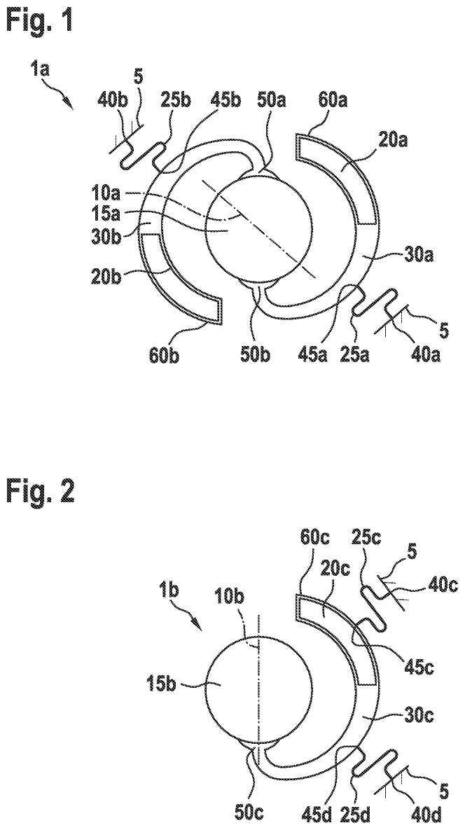

FIG. 1 schematically shows a top view of a first embodiment of a micromirror device as a micromechanical component 1a. The micromechanical component 1a comprises a bracket 5 and a micromirror, as adjustable portion 15a, which is arranged in an adjustable manner on the bracket 5. Additionally, the micromechanical component 1a comprises a first piezoelectric actuator as first bender actuator 20a and a first support structure 30a for the first bender actuator 20a. The first bender actuator 20a is arranged on the outer surface of the first support structure 30a. In this exemplary embodiment, the first support structure 30a is wing-shaped, in particular in a semi-circular wing shape. The first bender actuator 20a is configured to bend the first support structure 30a at least in the area of the first bender actuator 20a arranged on the first support structure 30a, such that the micromirror, as adjustable portion 15a, is displaceable relative to the bracket 5 around a first rotational axis 10a. The first support structure 30a is directly connected to the adjustable portion 15a. The micromechanical component 1a additionally comprises a first spring 25a, which is configured to suspend the first support structure 30a for the first bender actuator 20a and the adjustable portion 15a from the bracket 5. The first spring 25a does not impede the described twisting motion mechanism.

Additionally, the micromechanical component 1a has a second piezoelectric actuator as second bender actuator 20b and a second support structure 30b for the second bender actuator 20b. The second bender actuator 20b is arranged on an outer surface of the second support structure 30b. The second support structure 30b is also wing-shaped, in particular in a semi-circular wing shape. The second bender actuator 20b is configured to bend the second support structure 30b at least in the area of the second bender actuator 20b arranged on the second support structure 30b, such that the adjustable portion 15a is displaceable relative to the bracket 5 around the first rotational axis 10a. The second support structure 20b is also directly connected to the adjustable portion 15a. In this exemplary embodiment, the micromechanical component 1a comprises a third spring 25b, which is configured to suspend the second support structure 30b for the second bender actuator 20b and the adjustable portion 15a from the bracket 5.

The first 30a and the second support structure 30b are configured as spring elements in this exemplary embodiment. The two support structures 30a and 30b are formed from silicon. The first spring 25a and the third spring 25b are configured as meander-shaped springs in this exemplary embodiment and have a lower, in particular a significantly lower, spring stiffness than the first support structure 30a and the second support structure 30b.

The first bender actuator 20a and the second bender actuator 20b are arranged on an opposite end 60a and 60b of the respective support structure 30a and 30b to the adjustable portion 15a.

The first support structure 30a and the second support structure 30b engage with the adjustable portion 15a at opposite ends 50a and 50b of the adjustable portion 15a. A third point of application 45a of the first spring 25a on the first support structure 30a, as well as a fourth point of application 45b of the third spring 25b on the second support structure 30b are substantially arranged on the first rotational axis 10a. The first spring 25a and the second spring 25b are directly connected to the respective support structure 30a and 30b.

The micromechanical component 1a additionally comprises a control device (not shown here), which is configured to control the first 20a and the second bender actuator 20b by means of electrical signals such that the adjustable portion 15a can be moved into a resonant oscillating movement around the first rotational axis 10a relative to the bracket 5.

FIG. 2 schematically shows a second embodiment of a micromechanical component 1b. In contrast to the first embodiment, the micromechanical component 1b only comprises a single first support structure 30c for a first piezoelectric actuator as the first bender actuator 20c. Again, the first bender actuator 20c is configured to bend the first support structure 30c in the area of the first bender actuator 20c arranged on the first support structure 30c, such that the micromirror, as adjustable portion 15b, is displaceable relative to the bracket 5 around the first rotational axis 10b. The first support structure 20c is directly connected to the adjustable portion 15b. The first bender actuator 20c is arranged on an opposite end 60c of the first support structure 30c to the adjustable portion 15b. The micromechanical component 1b comprises a first spring 25c and a second spring 25d which are configured to suspend the first support structure 30c and the adjustable portion 15b from the bracket 5. In contrast to the first embodiment, a first point of application 45c of the first spring 25c on the first support structure 30c and a second point of application 45d of the second spring 25d on the first support structure 30c are arranged at an offset from the first rotational axis 10b. The first spring 25c and the second spring 25d are directly connected to the first support structure 30c. The first spring 25c and the second spring 25d are configured as meander-shaped springs and have a lower, in particular a significantly lower, spring stiffness than the first support structure 30c.

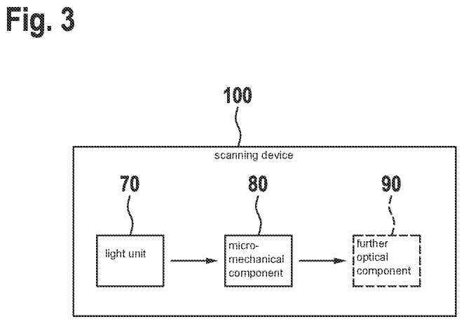

FIG. 3 schematically shows a microscanning device as scanning device 100. The scanning device 100 comprises a light unit 70 for generating light beams, in particular laser beams. Additionally, the scanning device 100 comprises a micromechanical component 80, as shown, by way of example, in FIGS. 1 and 2. The micromechanical component 100 is in particular configured as a micromirror device and serves to deflect the light beams. In particular, the scanning device 100 is configured as a lidar sensor. Alternatively, the scanning device 100 is configured as a microscanning device for data goggles. Further possible applications are scanning the environment with a depth measurement of the laser emitters, e.g. in smartphones, for which the micromirror is suitable due to its miniaturization. With the spectral analysis of an optical beam, the environment can also be analyzed for certain substances. In this context, a further optical component 90 for redirecting, in particular for guiding, the light beams into the retina of the data goggles user is optionally provided. The optical component 90 is in particular configured as a holographic optical element or as a waveguide.

What is claimed is:

1. A micromechanical component, comprising:
a bracket;
an adjustable portion arranged in an adjustable manner on the bracket;
a first bender actuator; and
a first support structure for the first bender actuator, wherein the first bender actuator is arranged in or on the first support structure;
wherein the first bender actuator is configured to bend the first support structure at least in an area of the first bender actuator arranged in or on the first support structure, such that the adjustable portion is displaceable relative to the bracket around a first rotational axis; and
wherein the first support structure is directly connected to the adjustable portion, and wherein the micromechanical component includes a first spring, wherein the first spring is configured to suspend the first support structure for the first bender actuator and the adjustable portion from the bracket.

2. The micromechanical component according to claim 1, further comprising:
a second spring configured to suspend the first support structure for the first bender actuator and the adjustable portion from the bracket.

3. The micromechanical component according to claim 2, wherein a first point of application of the first spring on the first support structure and a second point of application of the second spring on the first support structure are arranged at an offset from the first rotational axis.

4. The micromechanical component according to claim 2, further comprising:
a second bender actuator and a second support structure for the second bender actuator, wherein the second bender actuator is arranged in or on the second support structure, wherein the second bender actuator is configured to bend the second support structure at least in an area of the second bender actuator arranged in or on the second support structure, such that the adjustable portion is displaceable relative to the bracket around the first rotational axis, wherein the second support structure is directly connected to the adjustable portion; and
a third spring configured to suspend the second support structure for the second bender actuator and the adjustable portion from the bracket.

5. The micromechanical component according to claim 4, wherein the first support structure and the second support structure engage the adjustable portion at opposite ends of the adjustable portion.

6. The micromechanical component according to claim 4, wherein a third point of application of the first spring on the first support structure and a fourth point of application of the third spring on the second support structure are arranged on the first rotational axis.

7. The micromechanical component according to claim 5, wherein the first spring is directed connected to the first support structure and/or the second spring is directly connected to the second support structure and/or the third spring is directly connected to the third support structure.

8. The micromechanical component according to claim 4, wherein the first bender actuator and/or the second bender actuator, is configured as piezoelectric actuator.

9. The micromechanical component according to claim 4, wherein the first bender actuator is arranged on an opposite end of the first support structure to the adjustable portion and/or the second bender actuator is arranged on an opposite end of the second support structure to the adjustable portion.

10. The micromechanical component according to claim 4, wherein the first support structure and/or the second support structure in a semi-circular wing shape.

11. The micromechanical component according to claim 4, further comprising:
a control device configured to control the first bender actuator and/or the second bender actuator, using electrical signals such that the adjustable portion is moved into a resonant oscillating movement around the first rotational axis relative to the bracket.

12. The micromechanical component according to claim 1, wherein the adjustable portion is a micromirror.

13. The micromechanical component according to claim 4, wherein the first support structure and/or the second support structure, is configured as a spring element.

14. The micromechanical component according to claim 13, wherein the first spring and/or the second spring and/or the third spring, has a lower spring stiffness than the first support structure and/or the second support structure.

15. A microscanning device, comprising:
a micromechanical component including:
a bracket,
an adjustable portion arranged in an adjustable manner on the bracket,
a first bender actuator, and
a first support structure for the first bender actuator, wherein the first bender actuator is arranged in or on the first support structure,
wherein the first bender actuator is configured to bend the first support structure at least in an area of the first bender actuator arranged in or on the first support structure, such that the adjustable portion is displaceable relative to the bracket around a first rotational axis, and
wherein the first support structure is directly connected to the adjustable portion, and wherein the micromechanical component includes a first spring, wherein the first spring is configured to suspend the first support structure for the first bender actuator and the adjustable portion from the bracket.
